(19) United States
(12) Patent Application Publication
(10) Pub. No.: US 2026/0101781 A1
(43) Pub. Date: Apr. 9, 2026

(54) INTERCONNECT BRIDGE

(71) Applicant: QUALCOMM Incorporated, San Diego, CA (US)

(72) Inventors: Akshay BILAGI, San Diego, CA (US); Li-Sheng WENG, San Diego, CA (US)

(21) Appl. No.: 18/905,606

(22) Filed: Oct. 3, 2024

(51) Int. Cl. H01L 23/538; H01L 21/768

(52) U.S. Cl. CPC H10W 70/65; H10W 20/056; H10W 70/611

(57) ABSTRACT

A device includes an interconnect bridge and a substrate. The interconnect bridge includes a metal-dielectric composite structure that includes first dielectric layers and first metal layers patterned and interconnected to define interconnect contacts and first conductive paths. The interconnect bridge also includes an organic structural layer coupled to the metal-dielectric composite structure, and through-layer interconnects that extend through the organic structural layer and are electrically coupled to the first metal layers. The substrate includes second dielectric layers and second metal layers patterned and interconnected to define second conductive paths, and the interconnect bridge is embedded within the substrate. The first conductive paths of the metal-dielectric composite structure are electrically coupled to the second metal layers through the interconnect contacts and the through-layer interconnects of the interconnect bridge.

### FIELD

Various features relate to interconnect bridges.

### DESCRIPTION OF RELATED ART

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

In state-of-the-art electronic devices, there is generally an expectation that integrated device packages have a small form factor, a low cost, a tight power budget, and high performance. These various goals are often in conflict. For example, the increasing number of interconnect and interconnect levels between integrated circuits provides improved die-to-die communication, which improves performance. However, the increasing number of interconnect and interconnect levels can drive increases in the size of integrated device packages due to the need to provide more signal paths for die-to-die communications.

### SUMMARY

Various features relate to integrated circuit devices.

One example provides a device that includes an interconnect bridge and a substrate. The interconnect bridge includes a metal-dielectric composite structure including first dielectric layers and first metal layers patterned and interconnected to define interconnect contacts and first conductive paths. The interconnect bridge also includes an organic structural layer coupled to the metal-dielectric composite structure and through-layer interconnects that extend through the organic structural layer and are electrically coupled to the first metal layers. The substrate includes second dielectric layers and second metal layers patterned and interconnected to define second conductive paths. The interconnect bridge is embedded within the substrate, and the first conductive paths of the metal-dielectric composite structure are electrically coupled to the second metal layers through the interconnect contacts and the through-layer interconnects of the interconnect bridge.

Another example provides a method of fabrication that includes electrically coupling through-layer interconnects of an interconnect bridge to a patterned metal layer. The interconnect bridge includes a metal-dielectric composite structure including first dielectric layers and first metal layers patterned and interconnected to define first conductive paths. The interconnect bridge also includes an organic structural layer coupled to the metal-dielectric composite structure. The through-layer interconnects extend through the organic structural layer and are electrically coupled to the first metal layers. The method also includes forming additional layers on the patterned metal layer and the interconnect bridge to form a substrate. The substrate includes second dielectric layers and second metal layers patterned and interconnected to define second conductive paths, and the interconnect bridge is embedded within the substrate.

Another example provides an integrated device that includes an interconnect bridge and a substrate. The interconnect bridge includes a metal-dielectric composite structure that includes first dielectric layers and first metal layers patterned and interconnected to define interconnect contacts and first conductive paths. The interconnect bridge also includes an organic structural layer coupled to the metal-dielectric composite structure. The interconnect bridge includes through-layer interconnects that extend through the organic structural layer and that are electrically coupled to the first metal layers. The substrate includes second dielectric layers and second metal layers patterned and interconnected to define second conductive paths, and the interconnect bridge is embedded within the substrate. The first conductive paths of the metal-dielectric composite structure are electrically coupled to the second metal layers through the interconnect contacts and the through-layer interconnects of the interconnect bridge. A first die is coupled to the substrate, and a second die is coupled to the substrate and electrically coupled to the first die through the first conductive paths.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1A illustrates a schematic cross-sectional profile view of an exemplary device that includes an interconnect bridge embedded in a substrate.

FIG. 1B illustrates a schematic cross-sectional profile view of an example of the interconnect bridge of FIG. 1A.

FIG. 2 illustrates an exemplary sequence for fabricating an example of the interconnect bridge of FIGS. 1A and 1B.

FIG. 3A illustrates a first part of an exemplary sequence for fabricating an exemplary device that includes the interconnect bridge and the substrate of FIG. 1A.

FIG. 3B illustrates a second part of the exemplary sequence for fabricating the exemplary device that includes the interconnect bridge and the substrate of FIG. 1A.

FIG. 4 illustrates an exemplary flow diagram of a method of fabrication for an exemplary device that includes the interconnect bridge and the substrate of FIG. 1A.

FIG. 5 illustrates various electronic devices that may integrate an exemplary device that includes an interconnect bridge embedded in a substrate described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, various features are shown in block diagrams in order to avoid obscuring the aspects in unnecessary detail. Additionally, well-known circuits, structures and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnections are illustrated herein to highlight important features of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

In some drawings, multiple instances of a particular type of feature are shown. In some circumstances, fewer than all of such features may be identified using a reference number. For example, a single reference number may be shown and associated with a representative instance of the feature so as not to obscure other aspects of the drawings.

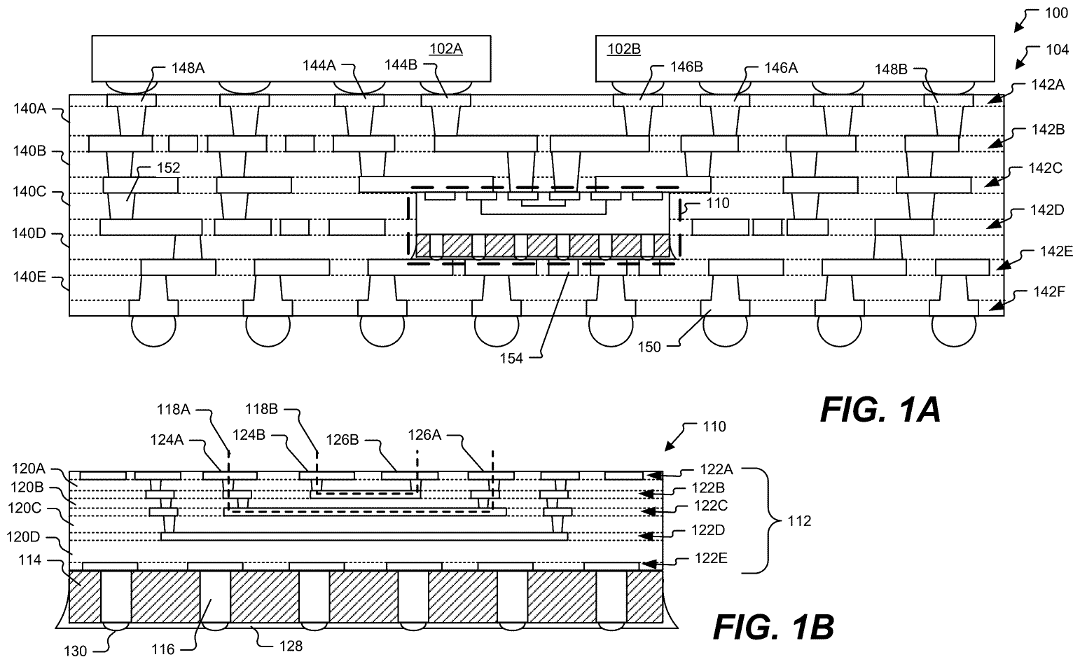

In some drawings in which multiple instances of a particular type of feature are used, different instances are distinguished by addition of a letter to the reference number. In this case, when the features as a group or a type are referred to herein (e.g., when no particular one of the features is being referenced), the reference number is used without a distinguishing letter. However, when one particular feature of multiple features of the same type is referred to herein, the reference number is used with the distinguishing letter. For example, referring to FIG. 1A, multiple metal layers are illustrated and associated with reference numbers 142A-142F. When referring to a particular one of these metal layers, such as a metal layer 142A, the distinguishing letter “A” is used. However, when referring to any arbitrary one of these metal layers or to these metal layers as a group, the reference number 142 is used without a distinguishing letter.

As used herein, the terms “comprise,” “comprises,” and “comprising” may be used interchangeably with “include,” “includes,” or “including. ” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

As used herein, the term “layer” includes a film, and is not construed as indicating a particular vertical or horizontal dimension unless otherwise stated. As used herein, the term “chiplet” may refer to an integrated circuit block, a functional circuit block, or other like circuit block specifically designed to work with one or more other chiplets to form a larger, more complex chiplet architecture.

Improvements in manufacturing technology and demand for lower cost and more capable electronic devices has led to increasing complexity of integrated circuits (ICs). Often, more complex ICs have more complex interconnection schemes to enable interaction between ICs of a device. The number of interconnect levels for circuitry has substantially increased due to the large number of ICs that are now interconnected in a state-of-the-art device.

These interconnections include back-end-of-line (BEOL) interconnect layers, which may refer to the conductive interconnect layers for electrically coupling to front end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middleof-line (MOL) interconnect layers, which interconnect to the FEOL active devices of an IC.

State-of-the-art electronic devices (e.g., portable computing devices, mobile communication devices, wearable devices, special purpose computing devices, etc.) demand a small form factor, low cost, a tight power budget, and high electrical performance. Integrated circuit package design has evolved to meet these divergent goals. One approach to reducing package size is to integrate multiple dies within a single package.

One example of a multi-die package is a two-dimensional (2D) package architecture, in which two or more dies are coupled to a package substrate side-by-side with one another. A similar approach is a 2.5D architecture, in which two or more devices are positioned side-by-side with one another on the package substrate, and one or more additional devices are stacked on at least one of the side-by-side devices. In each of these architectures, dies can interact with one another (e.g., via die-to-die (D2D) connections) and with off-package devices (e.g., via off-package connections). A challenge of such configurations is that D2D and off-package connections have different design criteria. For example, off-package connections are generally larger (e.g., in terms of line width, line spacing, etc.) than is needed for D2D connections. As a result, using the same fabrication techniques to form D2D and off-package connections results in larger package substrates. Furthermore, routing a large number of D2D connections using the large lines and large line spacings of off-package connections results in the use of additional layers in the substrate, which is more expensive and contrary to the goal of providing smaller packages.

Various approaches have been explored for achieving fine pitch D2D connectivity in electronics packaging. For example, in one approach, a substrate package is formed with a fine-pitch region that is fabricated using redistribution layer (RDL) fabrication techniques (as contrasted with substrate fabrication techniques). In this approach, some layers of the substrate are formed using lamination, pre-preg layup or other substrate fabrication techniques, and layers of the substrate that include the fine-pitch region are formed using RDL fabrication techniques (e.g., spin-coating or dry film techniques). One downside of this approach is that it entails forming RDL layers across a large area (e.g., an entirety of the area of the substrate) whereas the fine-pitch region is only formed in a relatively small area. This results in extra expense since RDL fabrication techniques are typically more expensive than substrate fabrication techniques. This approach also increases fabrication complexity due to combining the use of several different types of fabrication techniques for fabrication of the substrate.

Another solution is to use semiconductor fabrication techniques to form a bridge die. In this approach, the bridge die is formed by applying RDL to a semiconductor or glass substrate. One downside of this approach is that semiconductor fabrication tends to be more expensive than substrate fabrication. Another downside is that such bridge dies generally only provide electrical contacts on a single side due to the expense involved with forming through-silicon vias (TSVs) or through-glass vias (TGVs). Thus, electrical interconnects of bridge dies formed on semiconductor or glass substrates are limited.

Disclosed examples describe an interconnect bridge that includes a metal-dielectric composite structure disposed on an organic structural layer (e.g., a mold compound layer). The metal-dielectric composite structure is formed using RDL techniques and materials. The interconnect bridge is a discrete component or device that can be embedded in a substrate (e.g., a package substrate) to provide a fine-pitched routing area (e.g., for D2D interconnection) in the substrate. The disclosed interconnect bridge has the benefit of enabling fine pitch D2D routing in a manner that is less expensive and less technically complex than the approaches described above. For example, as compared to approaches that form RDLs as layers of a substrate, the disclosed interconnect bridge is less technically complex in that it does not entail the mixing of fabrication techniques (e.g., lamination and/or pre-preg layup for conventional substrate layers and spin-coating or dry film techniques for RDL). Rather, the interconnect bridge is formed as a discrete component that is subsequently embedded in the substrate. This approach reduces fabrication cost and complexity. As another example, the disclosed interconnect bridge can be fabricated using simpler and cheaper organic fabrication techniques, avoiding semiconductor/glass fabrication techniques which are more expensive and complex.

Another advantage of the disclosed interconnect bridge is that it is relatively simple to form electrical interconnects (e.g., copper posts) through the organic structural layer. Thus, the disclosed interconnect bridge can readily be formed to support electrical interconnection on two sides, providing routing options that are generally not available in bridge dies based on semiconductor or glass substrates.

### Exemplary Device Including an Interconnect Bridge Embedded in a Substrate

FIG. 1A illustrates a schematic cross-sectional profile view of an exemplary device 100 that includes an interconnect bridge 110 embedded in a substrate 104. In FIG. 1A, two or more dies 102 are electrically coupled to one another via the substrate 104 and the interconnect bridge 110. FIG. 1B illustrates a schematic cross-sectional profile view of an example of the interconnect bridge 110 of FIG. 1A.

In the example illustrated in FIG. 1A, the substrate 104 includes a set of dielectric layers 140 (including dielectric layers 140A, 140B, 140C, 140D, and 140E in FIG. 1A) and a set of metal layers 142 (including metal layers 142A, 142B, 142C, 142D, 142E, and 142F in FIG. 1A). The metal layers 142 are patterned and interconnected to define conductive paths of the substrate 104.

The interconnect bridge 110 includes a metal-dielectric composite structure 112 on an organic structural layer 114. In the example illustrated in FIG. 1B, the metal-dielectric composite structure 112 includes a set of dielectric layers 120 (including dielectric layers 120A, 120B, 120C, and 120D in FIG. 1B) and a set of metal layers 122 (including metal layers 122A, 122B, 122C, 122D, and 122E in FIG. 1B). The metal layers 122 are patterned and interconnected to define conductive paths 118 between contacts 124 and 126.

The substrate 104 is formed using conventional package substrate fabrication processes and materials. For example, the dielectric layers 140 can include or correspond to fiber reinforced polymer layers. To illustrate, each dielectric layer 140 can be formed by application (e.g., lay up or lamination) of a pre-preg layer that includes glass fibers (e.g., strands, mats, tape, etc.) embedded within or coated with a polymer. Epoxy resins are a good choice for the polymer as many epoxies can be partially cured to facilitate handling and later fully cured in-place to facilitate crosslinking and adhesion between adjacent layers. The fibers provide desired mechanical characteristics, e.g., resistance to warpage, in a relatively thin substrate.

As another example, the metal layers 142 of the substrate 104 can include metal foil layers, often applied as full sheets and subsequently patterned using subtractive techniques (e.g., etching or other removal techniques). As a result, the metal layers 142 tend to be relatively thick (as compared to deposited metal layers), to enable handling during full sheet placement. Additionally, the characteristic line width and line spacing (pitch) of lines of the metal layers 142 is limited due to limitations of the subtractive techniques used to pattern the metal layers 142 and clearances and dimensions that enable alignment of conductive vias 152 between the metal layers 142.

In contrast, the metal-dielectric composite structure 112 of the interconnect bridge 110 is formed using RDL fabrication techniques and materials. For example, the dielectric layers 120 of the interconnect bridge 110 can include or correspond to unreinforced polymer layers. To illustrate, the material of each dielectric layer 120 can be applied as a liquid or gel that is smoothed to form a substantially uniform layer using a spin-coating process or similar smoothing operation. Alternatively, the material of each dielectric layer 120 can be applied as a dry film. In either case, the material includes a polymer (e.g., a polyimide) without fiber reinforcement in order to form a thin, uniform layer. In some cases, the polymer can subsequently be patterned using subtractive techniques, and the patterned polymer can be used (possibly in combination with a patterned photoresist layer) to guide formation of a metal layer 122. In such cases, the metal layers 122 of the interconnect bridge 110 are formed using additive techniques, such as electroplating, chemical vapor deposition, physical vapor deposition, etc. Using such additive techniques enables formation of metal layers 122 with finer lines than lines of the metal layers 142 of the substrate 104. In this context, “finer” lines refers to lines that have a smaller characteristic line width, a smaller characteristic pitch, a smaller characteristic line thickness, or a combination thereof, relative to a reference (e.g., lines of the metal layers 142 in the example above).

Because the dielectric layers 120 are thin and generally unreinforced, and the metal layers 122 are also thin, the metal-dielectric composite structure 112 of the interconnect bridge 110 is coupled to the organic structural layer 114 to provide mechanical support for the metal-dielectric composite structure 112. For example, the organic structural layer 114 can include or correspond to a filled polymer material (e.g., an epoxy and filler composition), such as a mold compound. An advantage of using mold compound for the organic structural layer 114 is that mold compound materials are already used during BEOL fabrication processes and, as a result, are well understood, readily available, and can be applied using machinery and techniques that are commonly used in BEOL manufacturing.

An additional advantage of using mold compound or similar materials (e.g., a polymer and filler composition) is that through-layer interconnects 116 can be readily formed through such materials, which enables formation of electrical connections to the substrate 104 on two sides of the interconnect bridge 110. To illustrate, in the example illustrated in FIGS. 1A and 1B, the interconnect bridge 110 includes through-layer interconnects 116 that extend through the organic structural layer 114. The through-layer interconnects 116 are electrically coupled to the metal layers 122 of the metal-dielectric composite structure 112. The through-layer interconnects 116 can include or be coupled to solder caps 130 that are configured to electrically couple to contacts 154 on a metal layer (e.g., the metal layer 142E) of the substrate 104. For example, solder of the solder caps 130 can be reflowed to form solder connections to the contacts 154.

In the example illustrated in FIGS. 1A and 1B, a polymer underfill 128 is disposed between the solder connections formed by the solder caps 130 in a region between the interconnect bridge 110 and a layer (e.g., the metal layer 142E) of the substrate 104. The polymer underfill 128 provides mechanical support for the interconnect bridge 110. Additionally, the polymer underfill 128 can protect the solder connections from contamination during fabrication of the substrate 104.

The metal layers 142 of the substrate 104 are patterned and interconnected to define conductive paths that extend between various sets of contacts of the substrate 104. For example, the substrate 104 can include conductive paths to facilitate off-package connections to the dies 102 or other components of the device 100. To illustrate, the off-package connections can be formed via conductive paths that extend between contacts on the top of the substrate 104 (e.g., contacts 144, 146, or 148 of the metal layer 142A) and contacts on the bottom of the substrate 104 (e.g. contacts 150 of the metal layer 142F). Optionally, one or more of the off-package connections can extend through the interconnect bridge 110.

As another example, some conductive paths of the substrate 104 can extend between the interconnect bridge 110 and the die(s) 102 via one or more of the contacts 144, 146, 148, 150, and 154. For example, in FIG. 1A, the metal layers 142A-142C are patterned and interconnected to electrically couple the contact 144A of the substrate 104 to a contact 124A of the interconnect bridge 110 and to electrically couple the contact 146A of the substrate 104 to a contact 126A of the interconnect bridge 110. Likewise, the metal layers 142A-142C are patterned and interconnected to electrically couple the contact 144B of the substrate 104 to a contact 124B of the interconnect bridge 110 and to electrically couple the contact 146B of the substrate 104 to a contact 126B of the interconnect bridge 110. In this example, the contact 144A is electrically coupled to the contact 146A, and the contact 144B is electrically coupled to the contact 146B via conductive paths of the substrate 104 and the conductive paths 118 of the interconnect bridge 110. Thus, D2D connections can be routed through the substrate 104 and the interconnect bridge 110.

Each of the dies 102 can include integrated circuitry, such as a plurality of transistors and/or other circuit elements arranged and interconnected to form logic cells, memory cells, etc. Components of the integrated circuitry can be formed in and/or over a semiconductor substrate. Different implementations can use different types of transistors, such as a field effect transistor (FET), planar FET, finFET, a gate all around FET, or mixtures of transistor types. In some implementations, a front end-of-line (FEOL) process may be used to fabricate the integrated circuitry in and/or over the semiconductor substrate.

The dies 102 may include or correspond to particular IC devices that can be arranged and interconnected as a three-dimensional (3D) IC device or 2.5D IC device. In some implementations, one or more of the dies 102 include one or more microcontrollers, application specific integrated circuits (ASICs), field programmable gate arrays (FPGAs), central processing units (CPUs) having one or more processing cores, processing systems, system on chip (SoC) devices, or other circuitry and logic configured to facilitate the operations of the dies 102. Additionally, or alternatively, one or more of the dies 102 may include or be operated as a memory, such as a static random-access memory (SRAM), a dynamic random-access memory (DRAM), flash memory, read-only memory (ROM), programmable read-only memory (PROM), erasable programmable read-only memory (EPROM), electrically erasable programmable read-only memory (EEPROM), cache memory, a solid-state storage device (SSD), or a combination thereof.

Although the dies 102 are illustrated in FIG. 1A as directly coupled to the substrate 104 (e.g., via solder bumps), in some implementations, one or more of the dies 102 are electrically connected to, or integrated with, respective substrates. For example, the die 102B (and optionally one or more additional dies) can include a packaged IC device that, together with the die 102A, is coupled to the substrate 104 to form a package-on-package device. Further, although FIG. 1A illustrates two dies 102, in other examples, the device 100 can include more than two dies 102. In embodiments in which the device 100 includes more than two dies coupled to the substrate 104, the substrate 104 can include more than one interconnect bridge 110 embedded in the substrate 104 to provide D2D connections between the various dies 102.

It should be understood that the device 100 may include additional components, other components, fewer components, or a combination thereof, to support the functionality described herein. As non-limiting examples, the device 100 may include additional IC devices, more or fewer layers 140/142, additional dies 102, additional packages, additional interconnects, additional interconnect bridges 110, additional structures, other components, different components, or a combination thereof, to support the functionality and technical advantages disclosed herein. As one specific example, some of the metal layers 142 can be omitted from the substrate 104 to simplify fabrication of the substrate 104. To illustrate, metal layers 142C and 142D shown in FIG. 1A can be omitted in which case conductive vias extending to metal layer 142E can provide interconnection between metal layers 142 above the interconnect bridge 110 (e.g., the metal layer 142A, the metal layer 142B, the metal layer 142C, or a combination thereof) and metal layers below the interconnect bridge 110 (e.g., the metal layers 142E and 142F). Furthermore, the interconnect bridge 110 may include additional components, other components, fewer components, or a combination thereof, to support the functionality described herein. To illustrate, the interconnect bridge 110 can include more or fewer layers 120/122, additional structures, other components, different components, or a combination thereof, to support the functionality and technical advantages disclosed herein.

The device 100 thus enables compact (e.g., fine line) embedded D2D interconnection in an manner that is less expensive than embedded D3D interconnection schemes that form D2D interconnects using silicon or glass dies or by mixing RDL fabrication processes and substrate fabrication processes. In a particular implementation, the device 100 includes an interconnect bridge (e.g., the interconnect bridge 110) and a substrate (e.g., the substrate 104). The interconnect bridge (e.g., the interconnect bridge 110) includes a metal-dielectric composite structure (e.g., the metal-dielectric composite structure 112) that includes first dielectric layers (e.g., the dielectric layers 120A-120D) and first metal layers (e.g., the metal layers 122A-122E) patterned and interconnected to define contacts (e.g., the contacts 124) and first conductive paths (e.g., the conductive paths 118). The interconnect bridge (e.g., the interconnect bridge 110) also includes an organic structural layer (e.g., the organic structural layer 114) coupled to the metal-dielectric composite structure (e.g., the metal-dielectric composite structure 112). The interconnect bridge (e.g., the interconnect bridge 110) also includes through-layer interconnects (e.g., the through-layer interconnects 116) that extend through the organic structural layer (e.g., the organic structural layer 114) and are electrically coupled to the first metal layers (e.g., the metal layers 122A-122E). The substrate (e.g., the substrate 104) includes second dielectric layers (e.g., the dielectric layers 140A-140E) and second metal layers (e.g., the metal layers 142A-142F) patterned and interconnected to define second conductive paths. The interconnect bridge (e.g., the interconnect bridge 110) is embedded within the substrate (e.g., the substrate 104), and the first conductive paths (e.g., the conductive paths 118) of the metal-dielectric composite structure (e.g., the metal-dielectric composite structure 112) are electrically coupled to the second metal layers (e.g., the metal layers 142A-142F) through the contacts (e.g., the contacts 124) and the through-layer interconnects (e.g., the through-layer interconnects 116) of the interconnect bridge (e.g., the interconnect bridge 110).

### Exemplary Sequence for Fabricating an Interconnect Bridge

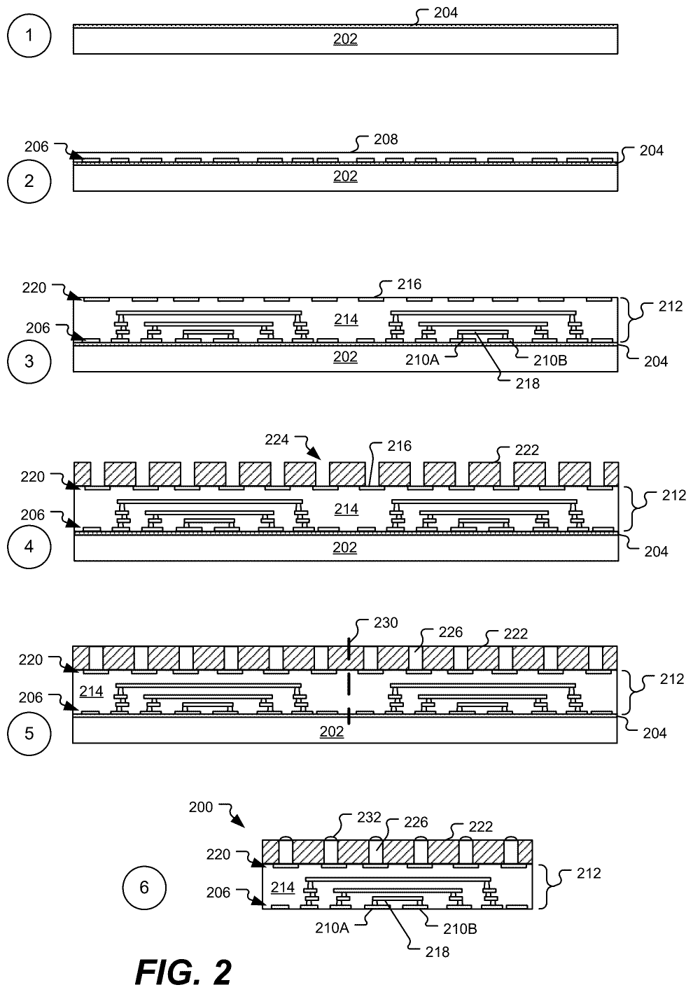

In some implementations, fabricating an interconnect bridge, such as the interconnect bridge 110 of FIGS. 1A and 1B, includes several processes. FIG. 2 illustrate an exemplary sequence for fabricating or providing an interconnect bridge, as described with reference to FIGS. 1A and 1B. In some implementations, the sequence of FIG. 2 may be used to provide (e.g., during fabrication of) the device 100 or the substrate 104 of FIG. 1A. Alternatively, the sequence of FIG. 2 may be used to provide (e.g., during fabrication of) an interconnect bridge (e.g., the interconnect bridge 110) as a discrete component that is available for use later (e.g., during a separate fabrication process) to form the device 100 or the substrate 104 of FIG. 1A.

It should be noted that the sequence of FIG. 2 may combine one or more stages in order to simplify and/or clarify the sequence for providing or fabricating an interconnect bridge. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIG. 2. Several of the Stages of the sequence illustrated in FIG. 2 show two or more interconnect bridges being formed concurrently (e.g., using wafer level, strip level, or panel level operations). In other implementations, a single interconnect bridge may be formed.

Stage 1 of FIG. 2 illustrates a state after formation of a release layer 204 on a carrier 202. The carrier 202 can include, for example, a glass panel or wafer used as a structural support for fabrication for various layers during the fabrication process. The release layer 204 can be formed by applying a liquid or gel release agent to the carrier 202 using one of various application processes, such as spraying, dipping, dispensing, painting, etc. Alternatively, the release layer 204 can include a solid or a dry film that is applied as a layer on the carrier 202.

Stage 2 illustrates a state after formation of a metal layer 206 and a dielectric layer 208 on the release layer 204. The metal layer 206 can be formed before the dielectric layer 208, or vice versa. For example, the metal layer 206 can be formed by forming a patterned photoresist layer on the release layer 204, forming a seed layer, and forming the metal layer 206 on the seed layer. In this example, the patterned photoresist layer can be removed, and the dielectric layer 208 can be formed over the release layer 204 and the metal layer 206.

As another example, a first portion of the dielectric layer 208 can be formed on the release layer 204 and patterned to form openings. In this example, a seed layer can be formed at least in the openings, and the metal layer 206 can be formed on the seed layer. In this example, a second portion of the dielectric layer 208 can be formed on the first portion of the dielectric layer 208 after the metal layer 206 is formed.

Irrespective of the order in which the metal layer 206 and the dielectric layer 208 are formed, the dielectric layer 208 can be formed using deposition techniques, such as spin-coating, to apply a liquid or gel. Alternatively, the dielectric layer 208 can be applied as a dry film. Generally, the dielectric layer 208 is formed using an unreinforced polymer, such as a polyimide.

The metal layer 206 generally includes copper. The metal layer 206 can include a multi-metal composite that is used as an underbump metallization layer. The metal layer 206 can be formed using any of various metal deposition techniques, such as plating, chemical vapor deposition, physical vapor deposition, sputtering, or printing. In some cases, the metal layer 206 can be formed using several such techniques. For example, the metal layer 206 can include a portion of the seed layer and one or more metals formed on the seed layer. In this example, the seed layer can be formed using sputtering or physical vapor deposition, and the one or more metals formed on the seed layer can be formed using plating.

Stage 3 illustrates a state after formation of one or more additional metal layers and one or more additional dielectric layers 214 to form a metal-dielectric composite structure 212. The one or more additional metal layers include at least a metal layer 220, corresponding to a final metal layer of the metal-dielectric composite structure 212. The one or more additional dielectric layers 214 separate the various metal layers (e.g., at least the metal layer 206 and the metal layer 220) of the metal-dielectric composite structure 212 from one another. The additional metal layer(s) and the additional dielectric layer(s) 214 can be formed using the same or similar materials and techniques to those described above with reference to Stage 2.

The various metal layers of the metal-dielectric composite structure 212 are patterned and interconnected to form conductive paths between contacts of the metal-dielectric composite structure 212. For example, as shown at Stage 3, the metal layer 206 includes a contact 210A and a contact 210B, which are electrically coupled to one another by conductive lines (e.g., a conductive line 218) of one or more of the metal layers and conductive vias interconnecting the metal layers. As another example, a contact 216 of the metal layer 220 can be electrically coupled to one or more other contacts of the metal layer 220 or of the metal layer 206. The count of metal layers included in the metal-dielectric composite structure 112 depends on the specific interconnections among contacts that are needed for a particular application. Thus, the metal layers illustrated in FIG. 2 are merely illustrative.

Stage 4 illustrates a state after formation of an organic structural layer 222 on the metal-dielectric composite structure 212. For example, the organic structural layer 222 can include an epoxy and filler composition, such as mold compound. In the example illustrated in FIG. 2, the organic structural layer 222 is patterned to define openings 224 to expose contacts 216 of the metal layer 220. In other examples, operations associated with Stages 4 and 5 of FIG. 2 can be reversed, in which case, the organic structural layer 222 is formed after formation of through-layer interconnects 226 (described with reference to Stage 5) and no patterning of the organic structural layer 222 is needed.

Stage 5 illustrates a state after formation of the through-layer interconnects 226. For example, the through-layer interconnects 226 can include or correspond to copper pillars formed on or coupled to the contacts 216 of the metal layer 220. As noted above, Stages 4 and 5 of FIG. 2 can be performed in the order illustrated or reversed. When performed in the order illustrated in FIG. 2, the through-layer interconnects 226 can be deposited on the contacts 216 as guided by the openings 224 of the organic structural layer 222 and possibly additional layers, such as photoresist layers. When Stages 4 and 5 are reversed relative to the order illustrated in FIG. 2, the through-layer interconnects 226 can be formed as conductive pillars on the contacts 216 (e.g., using plating as guided by a patterned photoresist layer) or conductive pillars can be formed separately and attached to the contacts (e.g., using solder connections). In this example, after the through-layer interconnects 226 are formed, over molding operations can be used to form the organic structural layer 222 at least partially encapsulating the through-layer interconnects 226. Whether the organic structural layer 222 or the through-layer interconnects 226 are formed first, further operations can be performed to planarize the organic structural layer 222, the through-layer interconnects 226, or both, after both are formed.

Stage 6 illustrates a state after individuation of an interconnect bridge 200 from the structure of Stage 5. For example, as part of Stage 6, the metal-dielectric composite structure 212 and the organic structural layer 222 can be separated from the carrier 202 and cut along a cut line 230 (illustrated at Stage 5) to form individual interconnect bridges (e.g., the interconnect bridge 200 of Stage 6). In some cases, the metal-dielectric composite structure 212 and the organic structural layer 222 can remain attached to the carrier 202 during individuation and subsequently be detached from the carrier 202.

The state illustrated at Stage 6 is also after formation of solder caps 232 on through-layer interconnects 226. The solder caps 232 can be formed before or after the metal-dielectric composite structure 212 and the organic structural layer 222 are separated from the carrier 202. Further, the solder caps 232 can be formed before or after individuation of the interconnect bridges.

Formation of the interconnect bridge 200 is complete at Stage 6. The interconnect bridge 200 corresponds to an example of the interconnect bridge 110 of FIGS. 1A and 1B and can include any of the features, layers, or other aspects and advantages described with reference to FIG. 1A or 1B. For example, the interconnect bridge 200 includes the metal-dielectric composite structure 212, which is an example of the metal-dielectric composite structure 112 of FIG. 1B. The interconnect bridge 200 also includes the organic structural layer 222, which is an example of the organic structural layer 114 of FIG. 1B. The interconnect bridge 200 also includes the through-layer interconnects 226, which are examples of the through-layer interconnects 116 of FIG. 1B. The interconnect bridge 200 also includes the solder caps 232, which are examples of the solder caps 130 of FIG. 1B.

Although certain Stages are illustrated in FIG. 2 in forming the interconnect bridge 200, other processes can be included in the fabrication of the interconnect bridge 200 without departing from the scope of the subject disclosure.

### Exemplary Sequence for Fabricating a Device Including an Interconnect Bridge Embedded in a Substrate

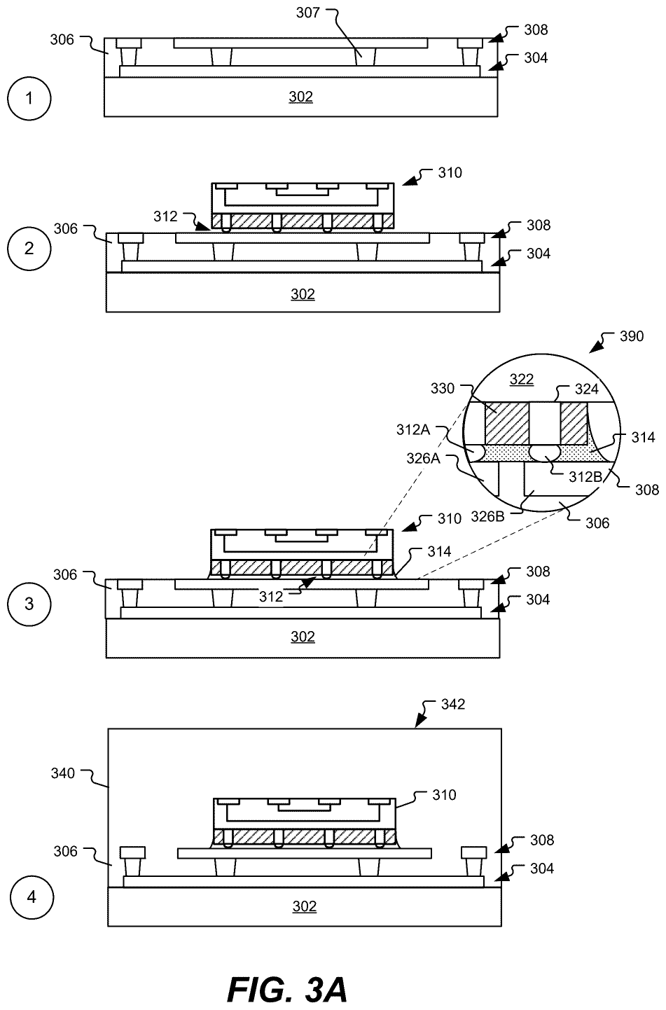

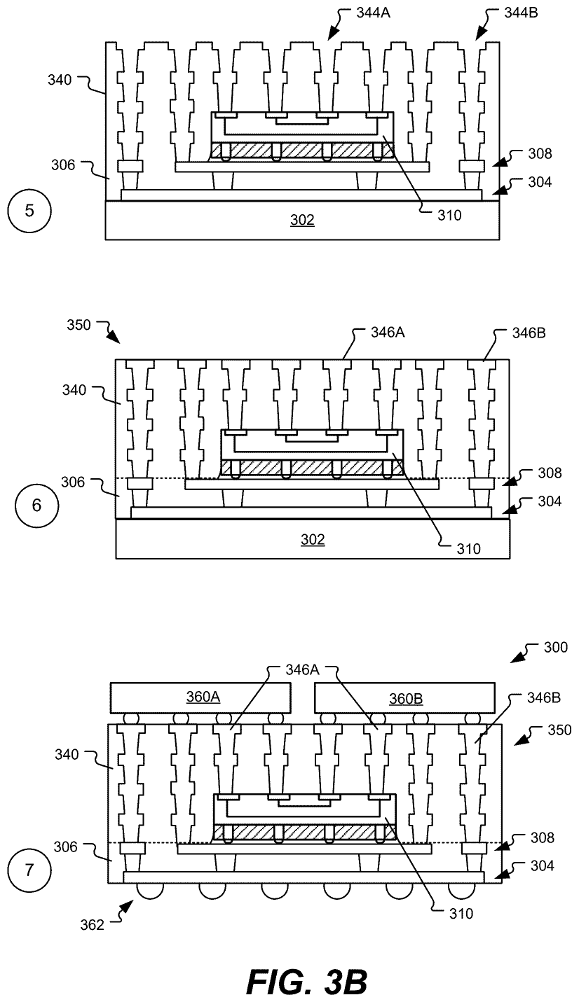

In some implementations, fabricating a device including a substrate with an embedded interconnect bridge (e.g., the device 100) includes several processes. FIGS. 3A and 3B illustrate an exemplary sequence for fabricating or providing a device that includes a substrate with an embedded interconnect bridge, as described with reference to FIGS. 1A and 1B.

It should be noted that the sequence of FIGS. 3A and 3B may combine one or more stages in order to simplify and/or clarify the sequence for providing or fabricating a substrate with an embedded interconnect bridge or a device including the substrate. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIGS. 3A and 3B. Each of the various stages of the sequence illustrated in FIGS. 3A and 3B shows a single device being formed. In other implementations, a plurality of devices can be formed concurrently (e.g., using wafer level, panel level, or strip level operations).

Stage 1 of FIG. 3A illustrates a state after formation of one or more metal layers (e.g., metal layers 304 and 308 in the example illustrated) and one or more dielectric layers (e.g., a dielectric layer 306 in the example illustrated). In FIG. 3A, the metal layer(s) 304, 308 and the dielectric layer(s) 306 are formed on a carrier 302, such as a carrier wafer, a platen, or other worksurface used to support substrate fabrication operations. Although the carrier 302 is shown at various Stages of FIGS. 3A and 3B, in some implementations, the carrier 302 can be omitted. For example, in some implementations, the dielectric layer 306 includes or corresponds to a core layer that is sufficiently stiff to support formation of other layers of the substrate (e.g., using lamination on one side or both sides of the core layer).

As described with reference to FIG. 1A, the metal layer(s) 304 and/or 308 can be formed by application of a metal foil that is subsequently patterned to form metal lines. Patterning of the metal foil can be performed using subtractive processes, such as etching, laser cutting, etc. The dielectric layer(s) 306 can be formed from a reinforced polymer material. For example, a pre-preg material including reinforcing fibers and a polymer (e.g., an epoxy resin) can be applied to the carrier 302. When the dielectric layer(s) 306 include a core layer, the core layer can be procured with unpatterned metal layers laminated on one side or both sides.

Conductive vias 307 can be formed through the dielectric layer(s) 306 to interconnect portions of the metal layers 304, 308 to form conductive paths. For example, laser or mechanical drilling can be used to form openings in the dielectric layer(s) 306 between the metal layers 304, 308, and metal can be deposited in the openings to form the conductive vias 307.

Stage 2 illustrates a state after an interconnect bridge 310 is coupled to the metal layer 308. The interconnect bridge 310 can include or correspond to an example of the interconnect bridge 110 of FIGS. 1A and 1B or the interconnect bridge 200 of FIG. 2. For example, the interconnect bridge can include a metal-dielectric composite structure coupled to an organic structural layer, as described with reference to FIGS. 1A-2.

Coupling the interconnect bridge 310 to the metal layer 308 can form conductive pathways between one or more metal layers of the metal-dielectric composite structure of the interconnect bridge 310 and contacts of the metal layer 308 via through-layer interconnects that extend through the organic structural layer of the interconnect bridge 310. For example, the interconnect bridge 310 can be electrically coupled to the metal layer 308 by solder connections 312. For example, the solder connections 312 can be formed via mass reflow of solder caps (e.g., the solder caps 130 of FIG. 1B), thermal compression bonding, or similar operations.

Stage 3 illustrates a state after a polymer underfill 314 is formed between the solder connections 312 in a region between the interconnect bridge 310 and the metal layer 308. For example, an underfill material can be injected into the region between the interconnect bridge 310 and the metal layer 308 and can flow between the solder connections 312 via capillary action.

An inset diagram 390 of Stage 3 illustrates more details of the region between the interconnect bridge 310 and the metal layer 308. In the inset diagram 390, portions of the interconnect bridge 310 are shown, including a portion of a metal-dielectric composite structure 322 coupled to an organic structural layer 330 and through-layer interconnects 324 extending through the organic structural layer 330. The inset diagram 390 also illustrates portions of two contacts 326 (e.g., a contact 326A and a contact 326B) of the metal layer 308 and solder connections 312A and 312B between respective through-layer interconnects 324 and the contacts 326 of the metal layer 308. The inset diagram 390 also illustrates the polymer underfill 314. In the inset diagram 390, the polymer underfill 314 is illustrated with a dotted fill to improve clarity.

Stage 4 illustrates a state after formation of one or more additional dielectric layers 340 on the metal layer 308 and the interconnect bridge 310. In some implementations, as part of Stage 4, one or more additional metal layers can also be formed. For example, one or more metal layers can be formed between the metal layer 308 and a top surface 342 of the dielectric layer(s) 340.

Stage 5 of FIG. 3B illustrates a state after formation of openings 344 in the dielectric layer(s) 340. In the example illustrated in FIG. 3B, the openings 344 include a first set of openings 344A to expose contacts of the interconnect bridge 310 and a second set of openings 344B to expose contacts of the metal layer 308. The openings 344 can be formed using laser drilling, mechanical drilling, or similar operations. In some implementations, one or more of the openings 344 can be formed in multiple steps. For example, the dielectric layer(s) 340 can include multiple layers, in which case, openings can be formed in one dielectric layer before a next dielectric layer is applied.

Stage 6 illustrates a state after formation of conductive vias 346 in the openings 344 of Stage 5. For example, metal deposition operations, such as plating, can be used to deposit metal within the openings 344 to form at least a first set of conductive vias 346A electrically coupled to contacts of the interconnect bridge 310 and a second set of conductive vias 346B electrically coupled to contacts of the metal layer 308.

Fabrication of a substrate 350 including an embedded interconnect bridge 310 is complete at Stage 6. Alternatively, the substrate 350 can be removed from the carrier 302 to complete fabrication of the substrate 350.

Stage 7 illustrates a state after dies 360 (e.g., dies 360A and 360B) are attached to the substrate 350 and a ball grid array (BGA) 362 is formed on the substrate 350. For example, the dies 360 can be attached to contacts of the conductive vias 346 to electrically couple the dies 360 to the metal layers 304, 308 and to the interconnect bridge 310. Conductive pathways of the interconnect bridge 310 provide D2D connections between the dies 360 to enable exchange of signals between the dies 360. Additionally, conductive pathways of the substrate 350 (e.g., of metal layers 304 and/or 308) enable signals to be communicated with off package devices via the BGA 362.

Formation of a device 300 is complete at Stage 7. For example, the device 300 includes an interconnect bridge (e.g., the interconnect bridge 310) and a substrate (e.g., the substrate 350). The interconnect bridge (e.g., the interconnect bridge 310) includes a metal-dielectric composite structure (e.g., the metal-dielectric composite structure 322) that includes first dielectric layers (e.g., the dielectric layers 214 of FIG. 2) and first metal layers (e.g., the metal layers 206 and 220 of FIG. 2) patterned and interconnected to define contacts (e.g., the contacts 210 of FIG. 2) and first conductive paths. The interconnect bridge (e.g., the interconnect bridge 310) also includes an organic structural layer (e.g., the organic structural layer 330) coupled to the metal-dielectric composite structure (e.g., the metal-dielectric composite structure 322). The interconnect bridge (e.g., the interconnect bridge 310) also includes through-layer interconnects (e.g., the through-layer interconnects 324) that extend through the organic structural layer (e.g., the organic structural layer 330) and are electrically coupled to the first metal layers (e.g., the metal layers 206 and 220 of FIG. 2). The substrate (e.g., the substrate 350) includes second dielectric layers (e.g., the dielectric layers 306 and 340) and second metal layers (e.g., the metal layers 304, 308, and optionally one or more additional metal layers) patterned and interconnected to define second conductive paths. The interconnect bridge (e.g., the interconnect bridge 310) is embedded within the substrate (e.g., the substrate 350), and the first conductive paths of the metal-dielectric composite structure (e.g., the metal-dielectric composite structure 322) are electrically coupled to the second metal layers (e.g., the metal layers 304, 308, and optionally one or more additional metal layers) through the contacts (e.g., the contacts 210 of FIG. 2) and the through-layer interconnects (e.g., the through-layer interconnects 324) of the interconnect bridge (e.g., the interconnect bridge 310).

Although certain Stages are illustrated in FIGS. 3A and 3B in forming the device 300, other processes can be included in the fabrication of the device 300 without departing from the scope of the subject disclosure. For example, fabricating the device 300 can include forming one or more additional metal layers during formation of the dielectric layer(s) 340. To illustrate, the one or more additional metal layers can include or correspond to one or more of the metal layers 142A-142E of FIG. 1A.

### Exemplary Flow Diagram of a Method for Fabricating a Device Including an Interconnect Bridge Embedded in a Substrate

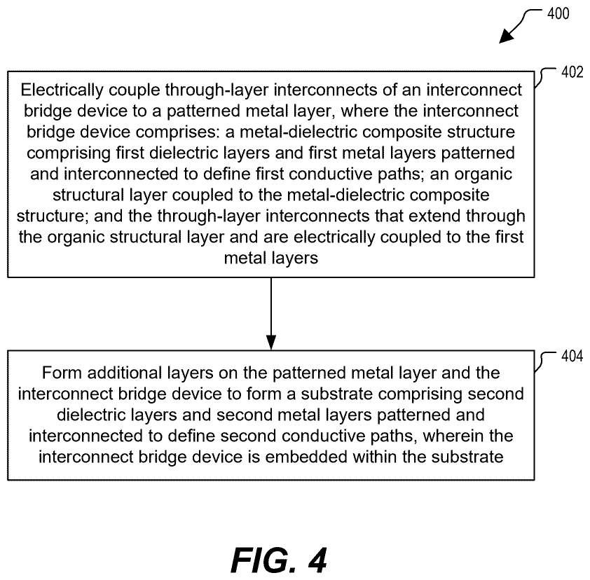

In some implementations, fabricating a device including an interconnect bridge embedded in a substrate includes several processes. FIG. 4 illustrates an exemplary flow diagram of a method 400 of fabricating an illustrative device that includes an interconnect bridge embedded in a substrate. In a particular aspect, one or more operations of the method 400 are performed by one or more processors of a fabrication system. In some implementations, operations of the method 400 may be stored as instructions by a non-transitory computer-readable storage medium, and the instructions may be executable by at least one processor to cause the at least one processor to perform operations of the method 400. In some implementations, the method 400 of FIG. 4 may be used to provide or fabricate the substrate 104 or the device 100 of FIG. 1A or to provide or fabricate the substrate 350 or the device 300 of FIG. 3B.

It should be noted that the method 400 of FIG. 4 may combine one or more processes in order to simplify and/or clarify the method for providing or fabricating an integrated circuit device. In some implementations, the order of the processes may be changed or modified.

The method 400 includes, at block 402, electrically coupling through-layer interconnects of an interconnect bridge to a patterned metal layer. For example, the interconnect bridge can include or correspond to the interconnect bridge 110 of FIGS. 1A and 1B, the interconnect bridge 200 of FIG. 2, or the interconnect bridge 310 of FIGS. 3A and 3B. The patterned metal layer can include or correspond to one of the metal layers 142 (e.g., the metal layer 142E) of the substrate 104 of FIG. 1A or the metal layer 308 of FIGS. 3A and 3B.

The interconnect bridge includes a metal-dielectric composite structure including first dielectric layers and first metal layers patterned and interconnected to define first conductive paths. The interconnect bridge also includes an organic structural layer coupled to the metal-dielectric composite structure and the through-layer interconnects that extend through the organic structural layer and are electrically coupled to the first metal layers. As an example, when the interconnect bridge includes or corresponds to the interconnect bridge 110 of FIG. 1B, the interconnect bridge 110 includes the metal-dielectric composite structure 112 that includes the dielectric layers 120A-120D and the metal layers 122A-122E patterned and interconnected to define the contacts 124 and the conductive paths 118. The interconnect bridge 110 also includes the organic structural layer 114 coupled to the metal-dielectric composite structure 112. The interconnect bridge 110 also includes the through-layer interconnects 116 that extend through the organic structural layer 114 and are electrically coupled to the metal layers 122A-122E.

An example of electrically coupling through-layer interconnects of an interconnect bridge to a patterned metal layer is described with reference to Stage 2 of FIG. 3A. For example, mass reflow or thermal compression bonding can be used to form the solder connections 312 between the through-layer interconnects 324 of the interconnect bridge 310 and the metal layer 308.

The method 400 includes, at block 404, forming additional layers on the patterned metal layer and the interconnect bridge to form a substrate that includes second dielectric layers and second metal layers patterned and interconnected to define second conductive paths, where the interconnect bridge is embedded within the substrate. For example, Stages 4-6 of FIGS. 3A and 3B describe examples of operations to form one or more additional layers on the patterned metal layer (e.g., the metal layer 308) and the interconnect bridge 310 and to form the conductive vias 346 defining conductive paths of the substrate 350. Optionally, the additional layers can include one or more additional dielectric layers and one or more additional metal layers. For example, in some embodiments, forming the additional layers includes applying a first fiber-reinforced polymer layer over the patterned metal layer and the interconnect bridge, forming a second patterned metal layer on the first fiber-reinforced polymer layer, and forming conductive vias through the first fiber-reinforced polymer layer to electrically couple the patterned metal layer and the second patterned metal layer.

In some implementations, the method 400 can also include forming the interconnect bridge. For example, forming the interconnect bridge can include forming a stack of layers on a carrier (e.g., the carrier 202 of FIG. 2) to form a metal-dielectric composite structure (e.g., the metal-dielectric composite structure 212 of FIG. 2) that includes first dielectric layers and first metal layers. Forming the interconnect bridge can also include forming an organic structural layer (e.g., the organic structural layer 222 of FIG. 2) on the metal-dielectric composite structure. Through-layer interconnects (e.g., the through-layer interconnects 226 of FIG. 2) that extend through the organic structural layer can be formed before or after formation of the organic structural layer. Forming the interconnect bridge can also include forming solder caps (e.g., the solder caps 232 of FIG. 2) on the through-layer interconnects.

In some embodiments, the method 400 also includes applying a polymer underfill between the solder connections before forming the additional layers. For example, the polymer underfill can include or correspond to the polymer underfill 128 of FIG. 1B or the polymer underfill 314 of FIG. 3A.

### Exemplary Electronic Devices

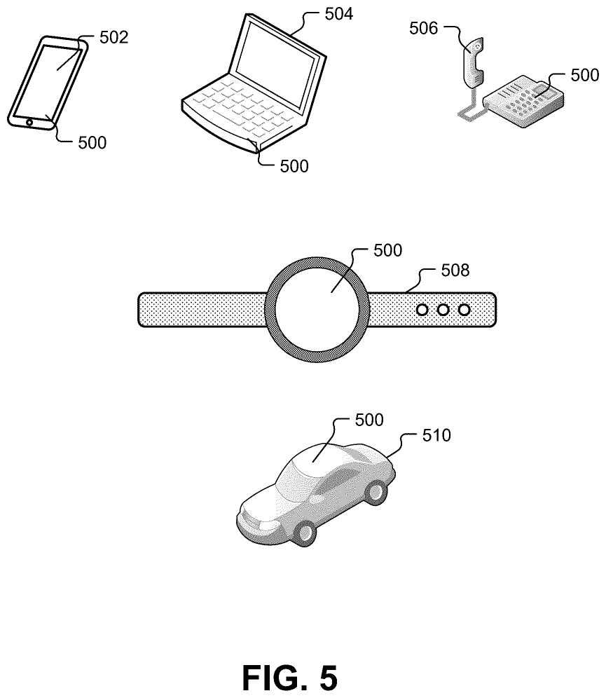

FIG. 5 illustrates various electronic devices that may include or be integrated with a device that includes an interconnect bridge embedded in a substrate, such as the device 100 of FIG. 1A or the device 300 of FIG. 3B. For example, a mobile phone device 502, a laptop computer device 504, a fixed location terminal device 506, a wearable device 508, or a vehicle 510 (e.g., an automobile or an aerial device) may include a device 500. The device 500 can include, for example, the device 100, the device 300, and/or any other device that includes the substrate 104 of FIG. 1A with the interconnect bridge 110 embedded therein or the substrate 350 of FIG. 3B with the interconnect bridge 310 embedded therein. The devices 502, 504, 506 and 508 and the vehicle 510 illustrated in FIG. 5 are merely exemplary. Other electronic devices may also feature the device 500 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1A-5 may be rearranged and/or combined into a single component, process, feature or function or embodied in several components, processes, or functions. Additional elements, components, processes, and/or functions may also be added without departing from the disclosure. It should also be noted FIGS. 1A-5 and its corresponding description in the present disclosure is not limited to dies and/or ICs. In some implementations, FIG. 1A-5 and its corresponding description may be used to manufacture, create, provide, and/or produce devices and/or integrated devices. In some implementations, a device may include a die, an integrated device, an embedded multi-chip package, an integrated passive device (IPD), a die package, an IC device, a device package, an IC package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first,” “second,” “third,” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate,” “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a device includes an interconnect bridge and a substrate. The interconnect bridge includes a metal-dielectric composite structure that includes first dielectric layers and first metal layers patterned and interconnected to define contacts and first conductive paths. The interconnect bridge also includes an organic structural layer coupled to the metal-dielectric composite structure and through-layer interconnects that extend through the organic structural layer and are electrically coupled to the first metal layers. The substrate includes second dielectric layers and second metal layers patterned and interconnected to define second conductive paths. The interconnect bridge is embedded within the substrate, and the first conductive paths of the metal-dielectric composite structure are electrically coupled to the second metal layers through the contacts and the through-layer interconnects of the interconnect bridge.

Example 2 includes the device of Example 1 and further includes solder connections that couple the through-layer interconnects to an interior metal layer of the second metal layers.

Example 3 includes the device of Example 1 or Example 2 and further includes a polymer underfill disposed between the solder connections in a region between the interconnect bridge and a layer of the substrate.

Example 4 includes the device of any of Examples 1 to 3, where the organic structural layer includes mold compound.

Example 5 includes the device of any of Examples 1 to 4, where the organic structural layer includes an epoxy and filler composition.

Example 6 includes the device of any of Examples 1 to 5, where one or more of the second dielectric layers include fiber-reinforced polymer.

Example 7 includes the device of any of Examples 1 to 6, where the first dielectric layers include unreinforced polymer.

Example 8 includes the device of any of Examples 1 to 7, where: a top metal layer of the substrate defines, on a first side of the substrate, a first set of contacts; a second set of contacts electrically coupled to the first set of contacts through the interconnect bridge and a first set of conductive paths of the second metal layers; and a third set of contacts, and where a bottom metal layer of the substrate defines, on a second side of the substrate opposite the first side, a fourth set of contacts electrically coupled to the third set of contacts by a second set of conductive paths of the second metal layers.

Example 9 includes the device of any of Examples 1 to 8, where the first metal layers are patterned to define first lines with a first characteristic line width, and the second metal layers are patterned to define second lines with a second characteristic line width greater than the first characteristic line width.

Example 10 includes the device of any of Examples 1 to 9, where the first metal layers are patterned to define first lines with a first characteristic pitch, and the second metal layers are patterned to define second lines with a second characteristic pitch greater than the first characteristic pitch.

Example 11 includes the device of any of Examples 1 to 10, where the first metal layers have a first characteristic thickness, and the second metal layers have a second characteristic thickness greater than the first characteristic thickness.

According to Example 12, a method includes electrically coupling through-layer interconnects of an interconnect bridge to a patterned metal layer. The interconnect bridge includes a metal-dielectric composite structure including first dielectric layers and first metal layers patterned and interconnected to define first conductive paths. The interconnect bridge also includes an organic structural layer coupled to the metal-dielectric composite structure and the through-layer interconnects that extend through the organic structural layer and are electrically coupled to the first metal layers. The method also includes forming additional layers on the patterned metal layer and the interconnect bridge to form a substrate. The substrate includes second dielectric layers and second metal layers patterned and interconnected to define second conductive paths, where the interconnect bridge is embedded within the substrate.

Example 13 includes the method of Example 12, where said electrically coupling the through-layer interconnects of the interconnect bridge to the patterned metal layer includes forming solder connections between the through-layer interconnects and contacts of the patterned metal layer.

Example 14 includes the method of Example 12 or Example 13 and further includes applying a polymer underfill between the solder connections before forming the additional layers.

Example 15 includes the method of any of Examples 12 to 14, where the organic structural layer includes mold compound.

Example 16 includes the method of any of Examples 12 to 15, where the organic structural layer includes an epoxy and filler composition.

Example 17 includes the method of any of Examples 12 to 16, where the first dielectric layers include unreinforced polymer.

Example 18 includes the method of any of Examples 12 to 17, where said forming the additional layers includes: applying a first fiber-reinforced polymer layer over the patterned metal layer and the interconnect bridge; forming a second patterned metal layer on the first fiber-reinforced polymer layer; and forming conductive vias through the first fiber-reinforced polymer layer to electrically couple the patterned metal layer and the second patterned metal layer.

Example 19 includes the method of Example 18, where the first metal layers of the interconnect bridge define lines with a first characteristic line width, and where the patterned metal layer and the second patterned metal layer define lines with a second characteristic line width greater than the first characteristic line width.

Example 20 includes the method of Example 18 or Example 19, where the first metal layers of the interconnect bridge define lines with a first characteristic pitch, and where the patterned metal layer and the second patterned metal layer define lines with a second characteristic pitch greater than the first characteristic pitch.

Example 21 includes the method of any of Examples 18 to 20, where the first metal layers of the interconnect bridge have a first characteristic thickness, and where the patterned metal layer and the second patterned metal layer have a second characteristic thickness greater than the first characteristic thickness.

Example 22 includes the method of any of Examples 12 to 21, where said forming the additional layers includes forming a top metal layer of the substrate to define: a first set of contacts; a second set of contacts electrically coupled to the first set of contacts through the interconnect bridge and conductive paths of the additional layers; and a third set of contacts.

Example 23 includes the method of Example 22 and further includes electrically coupling a first die to the first set of contacts; and electrically coupling a second die to the second set of contacts to interconnect the first die and the second die through the interconnect bridge.

Example 24 includes the method of Example 22 or Example 23 and further includes, before said electrically coupling the through-layer interconnects of the interconnect bridge to the patterned metal layer: forming a bottom metal layer that defines a fourth set of contacts, where, after formation of the substrate, the fourth set of contacts are electrically coupled to the third set of contacts.

Example 25 includes the method of any of Examples 12 to 24 and further includes, before said electrically coupling the through-layer interconnects to the patterned metal layer, forming the interconnect bridge, where said forming the interconnect bridge includes: forming the first dielectric layers and the first metal layers on a carrier to define a stack of layers; forming the organic structural layer on a top layer of the stack of layers; forming the through-layer interconnects; and forming solder caps on the through-layer interconnects.

Example 26 includes the method of Example 25, where said electrically coupling the through-layer interconnects to the patterned metal layer includes applying heat, pressure, or both, to cause the solder caps to attach to contacts of the patterned metal layer.

According to Example 27, an integrated device includes an interconnect bridge and a substrate. The interconnect bridge includes a metal-dielectric composite structure including first dielectric layers and first metal layers patterned and interconnected to define contacts and first conductive paths. The interconnect bridge also includes an organic structural layer coupled to the metal-dielectric composite structure and through-layer interconnects that extend through the organic structural layer and are electrically coupled to the first metal layers. The substrate includes second dielectric layers and second metal layers patterned and interconnected to define second conductive paths, and the interconnect bridge is embedded within the substrate. The first conductive paths of the metal-dielectric composite structure are electrically coupled to the second metal layers through the contacts and the through-layer interconnects of the interconnect bridge. A first die is coupled to the substrate, and a second die is coupled to the substrate and electrically coupled to the first die through the first conductive paths.

Example 28 includes the integrated device of Example 27 and further includes solder connections that couple the through-layer interconnects to an interior metal layer of the second metal layers.

Example 29 includes the integrated device of Example 28 and further includes a polymer underfill disposed between the solder connections in a region between the interconnect bridge and a layer of the substrate.

Example 30 includes the integrated device of any of Examples 27 to 29, where the organic structural layer includes mold compound.

Example 31 includes the integrated device of any of Examples 27 to 30, where the organic structural layer includes an epoxy and filler composition.

Example 32 includes the integrated device of any of Examples 27 to 31, where one or more of the second dielectric layers includes fiber-reinforced polymer.

Example 33 includes the integrated device of any of Examples 27 to 32, where the first dielectric layers include unreinforced polymer.

Example 34 includes the integrated device of any of Examples 27 to 33, where the first metal layers are patterned to define first lines with a first characteristic line width, and the second metal layers are patterned to define second lines with a second characteristic line width greater than the first characteristic line width.

Example 35 includes the integrated device of any of Examples 27 to 34, where the first metal layers are patterned to define first lines with a first characteristic pitch, and the second metal layers are patterned to define second lines with a second characteristic pitch greater than the first characteristic pitch.

Example 36 includes the integrated device of any of Examples 27 to 35, where the first metal layers have a first characteristic thickness, and the second metal layers have a second characteristic thickness greater than the first characteristic thickness.

Example 37 includes the integrated device of any of Examples 27 to 36, where a top metal layer of the substrate defines, on a first side of the substrate: a first set of contacts electrically coupled to the first die; a second set of contacts electrically coupled to the second die and electrically coupled to the first set of contacts through the interconnect bridge and a first set of conductive paths of the second metal layers; and a third set of contacts electrically coupled to the first die, the second die, or both. A bottom metal layer of the substrate defines, on a second side of the substrate opposite the first side, a fourth set of contacts electrically coupled to the third set of contacts by a second set of conductive paths of the second metal layers.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A device comprising:
an interconnect bridge comprising:
a metal-dielectric composite structure comprising first dielectric layers and first metal layers patterned and interconnected to define contacts and first conductive paths;
an organic structural layer coupled to the metal-dielectric composite structure; and
through-layer interconnects that extend through the organic structural layer and are electrically coupled to the first metal layers; and
a substrate comprising second dielectric layers and second metal layers patterned and interconnected to define second conductive paths, wherein the interconnect bridge is embedded within the substrate, and wherein the first conductive paths of the metal-dielectric composite structure are electrically coupled to the second metal layers through the contacts and the through-layer interconnects of the interconnect bridge.

2. The device of claim 1, further comprising solder connections that couple the through-layer interconnects to an interior metal layer of the second metal layers.

3. The device of claim 2, further comprising a polymer underfill disposed between the solder connections in a region between the interconnect bridge and a layer of the substrate.

4. The device of claim 1, wherein the organic structural layer comprises an epoxy and filler composition.

5. The device of claim 1, wherein one or more of the second dielectric layers comprise fiber-reinforced polymer.

6. The device of claim 1, wherein the first dielectric layers comprise unreinforced polymer.

7. The device of claim 1, wherein:
a top metal layer of the substrate defines, on a first side of the substrate:
a first set of contacts;
a second set of contacts electrically coupled to the first set of contacts through the interconnect bridge and a first set of conductive paths of the second metal layers; and
a third set of contacts; and
a bottom metal layer of the substrate defines, on a second side of the substrate opposite the first side, a fourth set of contacts electrically coupled to the third set of contacts by a second set of conductive paths of the second metal layers.

8. The device of claim 1, wherein the first metal layers are patterned to define first lines with a first characteristic line width and the second metal layers are patterned to define second lines with a second characteristic line width greater than the first characteristic line width.

9. The device of claim 1, wherein the first metal layers are patterned to define first lines with a first characteristic pitch and the second metal layers are patterned to define second lines with a second characteristic pitch greater than the first characteristic pitch.

10. The device of claim 1, wherein the first metal layers have a first characteristic thickness and the second metal layers have a second characteristic thickness greater than the first characteristic thickness.

11. A method comprising:
electrically coupling through-layer interconnects of an interconnect bridge to a patterned metal layer, the interconnect bridge comprising:
a metal-dielectric composite structure comprising first dielectric layers and first metal layers patterned and interconnected to define first conductive paths;
an organic structural layer coupled to the metal-dielectric composite structure; and
the through-layer interconnects that extend through the organic structural layer and are electrically coupled to the first metal layers; and
forming additional layers on the patterned metal layer and the interconnect bridge to form a substrate comprising second dielectric layers and second metal layers patterned and interconnected to define second conductive paths, wherein the interconnect bridge is embedded within the substrate.

12. The method of claim 11, wherein said electrically coupling the through-layer interconnects of the interconnect bridge to the patterned metal layer comprises forming solder connections between the through-layer interconnects and contacts of the patterned metal layer.

13. The method of claim 12, further comprising applying a polymer underfill between the solder connections before forming the additional layers.

14. The method of claim 11, wherein said forming the additional layers comprises:
applying a first fiber-reinforced polymer layer over the patterned metal layer and the interconnect bridge;
forming a second patterned metal layer on the first fiber-reinforced polymer layer; and
forming conductive vias through the first fiber-reinforced polymer layer to electrically couple the patterned metal layer and the second patterned metal layer.

15. An integrated device comprising:
an interconnect bridge comprising:
a metal-dielectric composite structure comprising first dielectric layers and first metal layers patterned and interconnected to define contacts and first conductive paths;
an organic structural layer coupled to the metal-dielectric composite structure; and
through-layer interconnects that extend through the organic structural layer and are electrically coupled to the first metal layers;
a substrate comprising second dielectric layers and second metal layers patterned and interconnected to define second conductive paths, wherein the interconnect bridge is embedded within the substrate, and wherein the first conductive paths of the metal-dielectric composite structure are electrically coupled to the second metal layers through the contacts and the through-layer interconnects of the interconnect bridge;
a first die coupled to the substrate; and
a second die coupled to the substrate and electrically coupled to the first die through the first conductive paths.

16. The integrated device of claim 15, further comprising solder connections that couple the through-layer interconnects to an interior metal layer of the second metal layers, and a polymer underfill disposed between the solder connections in a region between the interconnect bridge and a layer of the substrate.

17. The integrated device of claim 15, wherein the organic structural layer comprises mold compound.

18. The integrated device of claim 15, wherein one or more of the second dielectric layers comprises fiber-reinforced polymer.

19. The integrated device of claim 15, wherein the first dielectric layers comprise unreinforced polymer.

20. The integrated device of claim 15, wherein:
a top metal layer of the substrate defines, on a first side of the substrate:
a first set of contacts electrically coupled to the first die;
a second set of contacts electrically coupled to the second die and electrically coupled to the first set of contacts through the interconnect bridge and a first set of conductive paths of the second metal layers; and
a third set of contacts electrically coupled to the first die, the second die, or both; and
a bottom metal layer of the substrate defines, on a second side of the substrate opposite the first side, a fourth set of contacts electrically coupled to the third set of contacts by a second set of conductive paths of the second metal layers.
